(19) United States
(12) Patent Application Publication
(10) Pub. No.: US 2004/0113151 A1
(43) Pub. Date: Jun. 17, 2004

(54) CMOS image sensor

(75) Inventor: Hirokazu Sekine, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/680,179

(22) Filed: Oct. 8, 2003

(30) Foreign Application Priority Data
Oct. 11, 2002 (JP) 2002-298662

(51) Int. Cl. H01L 29/04

(52) U.S. Cl. 257/72

(57) ABSTRACT

In a CMOS image sensor comprising a plurality of unit cells arranged in a matrix array in the vertical and the horizontal directions to read out a signal from first and second photodiodes 52a, 52b through a common transistor portion, the first and the second photodiodes are arranged separately to each other in the vertical direction. The transistor portion comprises a pair of readout transistors, a reset transistor, an amplifying transistor and a selecting transistor. The pair of the readout transistors and the reset transistor are located adjacent to a floating diffusion region of an approximately rectangular shape. Four gate lines controlling the gates of respective transistors are extended in the horizontal direction of the matrix, and form at least one double-layered line.

### CROSS-REFERENCE TO RELATED APPLICATIONS

This application is based upon and claims the benefit of priority from the prior Japanese Patent Application No. 2002-298662 filed on Oct. 11, 2002; the entire contents of which are incorporated herein by reference.

### BACKGROUND OF THE INVENTION

1. Field of the Invention

The present invention relates to a CMOS image sensor in which active picture elements thereof are arranged on a semiconductor substrate in a matrix array to be X-Y addressable.

2. Description of the Related Art

An active picture element of the CMOS image sensor comprises a photodiode formed on a semiconductor substrate as a photodetector and a plurality of CMOS transistors transmitting and amplifying signals generated by the photodiode being irradiated by a light. A picture element portion is formed by a plurality of picture element unit cells comprising a combination of these elements on a semiconductor substrate in a matrix array. Fundamentally, it is necessary to combine a reset transistor, an amplifying transistor, and a selecting transistor for row addressing.

A structure in which a plurality of photodiodes share one set of the above combination to make signal processing be more effective is also well known. Usually, a sensor having a common amplifier shared by a pair of photodiodes is put to practical use for such as digital cameras, mobile apparatus, and cellular phones with cameras. In this structure, signal switching to derive the signals from the pair of photodiodes one by one is carried out by attaching a readout transistor to each diode. There also is a structure provided with a readout portion including a timing generating circuit, a vertical line scanning circuit, a noise canceling circuit, a horizontal line scanning circuit, and an output amplifier in the periphery of the picture element portion.

Referring to FIG. 10 to FIG. 12, prior art examples will be hereinafter explained. FIG. 10 is a diagram of matrix arrangement; FIG. 11 is a circuit diagram of the principal part thereof; FIG. 12 shows a layout of the principal part.

In FIG. 10, the picture element portion 1 is constituted of a plurality of unit cells Ce arranged two-dimensionally in matrix approximately in the shape of the square lattice, in which the picture element of one unit cell Ce comprises first and second photodiodes 12a, 12b. As shown in FIG. 11, the first and the second photodiodes 12a, 12b are connected to sources of readout transistors 13a, 13b provided corresponding thereto respectively, and gates 14a, 14b of the readout transistor 13a, 13b are connected to readout lines 15a, 15b supplying a readout pulse.

Drains of the readout transistors 13a, 13b are formed by a common floating diffusion region 16, which is connected to both a gate 18 of an amplifying transistor 17 and a source 20 of a reset transistor 19. A drain 21 of the amplifying transistor 17 and a source of a selecting transistor 22 are common. A drain 23 of the selecting transistor 22 is connected to a power line 24, and a selecting line 26 supplying a selecting pulse is connected to a gate 25 of the selecting transistor 22. A source of the amplifying transistor 17 is formed by a source diffusion region 27, which is connected to a signal line 28.

On the other hand, a drain of the reset transistor 19 and the drain 23 of the selecting transistor 22 of the neighboring unit cell Ce are common, and are connected to the power line 24 of a reset drain power source. A gate 29 of the reset transistor 19 is connected to a reset line 30 supplying a reset pulse.

As shown in FIG. 12, the layout thereof is that either the first photodiodes 12a or the second photodiodes 12b both being rectangular are positioned apart from one another by a predetermined distance in the horizontal direction, and the first diode 12a and the second photodiode 12b are alternately located a predetermined distance apart in the vertical direction. Between the first photodiode 12a and the neighboring second photodiode 12b of the same unit cell Ce in the vertical direction, readout lines 15a, 15b are provided lengthwise in the horizontal direction on the middle of the pattern in such a manner that they interpose a floating diffusion region 16. The readout lines constitute the gates 14a, 14b of the readout transistors 13a, 13b, to supply a readout pulse.

On the upper side of the first photodiode 12a in the vertical direction, reset lines 30 where the gate 29 of the reset transistor 19 to which a reset pulse is applied is formed are provided lengthwise in the horizontal direction a predetermined distance apart from each other. On the other hand, between the second photodiode 12b and the first photodiode 12a of the neighboring unit cell on the lower side, selecting lines 26 where the gate 25 of the selecting transistor 22 to which a selecting pulse is supplied is formed are provided lengthwise in the horizontal direction a predetermined distance apart from the reset line 30 of the same neighboring unit cell on the lower side of the second photodiode 12b in the vertical direction.

On the middle of the reset line 30 to be the gate 29 of the reset transistor 19, the source 20 on the lower side and the drain common to the drain 23 of the selecting transistor 22 of the neighboring unit cell on the upper side are formed respectively. Between the readout line 15b and the selecting line 26 interposing the second photodiode 12b, the gate 18 of the amplifying transistor 17 is formed in the vicinity of the second photodiode 12b. The source diffusion region 27 of the amplifying transistor 17 is formed on the upper side of the gate 18 in the vertical direction. The drain 21 of the amplifying transistor 17, which doubles as the source of the selecting transistor 22, is formed on the lower side of the gate 18.

Between the selecting line 26 and the reset line 30 of the neighboring unit cell on the lower side in the vertical direction, the drain 23 of the selecting transistor 22, which doubles as the drain of the reset transistor 19 of the neighboring unit cell, is formed corresponding to the source of the selecting transistor 22.

For each unit cell having the pattern of the above-mentioned structure, the power line 24 of aluminum is laid to the drain 23 of the selecting transistor 22, which doubles as the drain of the reset transistor 19 of each unit cell arranged in the vertical direction, in order to connect them together. In the same way, for the source diffusion region 27 of the amplifying transistor 17 of each unit cell Ce arranged in the vertical direction, the signal line 28 outputting a signal read out by a readout pulse is laid in order to connect them together.

In every unit cell Ce, an aluminum line connects, for example, the connecting line 31 that connects the floating diffusion region 16 to the gate 18 of the amplifying transistor 17, and the connecting line 32 that connects the floating diffusion region 16 to the source 20 of the reset transistor 19, are laid by aluminum lines in order to connect the floating diffusion region 16, the gate 18 of the amplifying transistor 17, and the source 20 of the reset transistor 19 together. In addition, the gates 14a, 14b, 18, 25, and 29 of the transistors 13a, 13b, 17, 19, and 22 are formed by polycrystalline silicon.

In the prior art mentioned above, one unit cell Ce had to be comprised of the first photodiode 12a, the second photodiode 12b, readout transistors 13a, 13b, the amplifying transistor 17, the reset transistor 19, and the selecting transistor 22. In addition, the readout lines 15a, 15b, the selecting line 26, and the reset line 30 had to be formed so as to lie on the same surface corresponding to the above, and the power line 24, the signal line 28, and the connecting lines 31, 32 had to be prepared by aluminum lines. Consequently, the areas of the first photodiode 12a and the second photodiode 12b became approximately 20 to 30% of the whole area of the unit cell Ce at most, and improving the resolution of the sensor was limited because designing high integration to improve the resolution was difficult to be realized. In addition, the readout line 15a crossing the connecting line 32 results in forming a cross point 40.

On the other hand, the source portion 20 of the reset transistor and the connecting line 32 in addition to the floating diffusion layer 16 increased the capacitance so that variation of the signal output to signal charge, i.e. the amplification gain was decreased. That hindered realization of a high sensitive sensor.

### BRIEF SUMMARY OF THE INVENTION

The present invention is intended to provide a CMOS image sensor that can be highly integrated without miniaturizing elements and lines in particular and have the resolution thereof improved, etc., by positioning effectively the elements and lines constituting the unit cell, in the light of the circumstances mentioned above.

A CMOS image sensor according to an aspect of the present invention has a plurality of unit cells arranged in a matrix array on a semiconductor substrate, the unit cell being constituted of a photodiode and a plurality of MOS transistors,

wherein the unit cell comprises a first and a second photodiodes, a first readout transistor connected to the first photodiode to read out signals thereof, a second readout transistor connected to the second photodiode to read out signals thereof, a floating diffusion region to which the signals are transmitted by being connected to the first and the second readout transistors, a reset transistor connected to the floating diffusion region for resetting a potential of the region, an amplifying transistor whose gate is connected to the floating diffusion region for amplifying the signals, and a selecting transistor selectively addressing the amplifying transistor,

the unit cell being connected to two readout lines of the first and the second readout transistors, a reset line of the reset transistor, and a selecting line of the selecting transistor, which are four gate lines extending in the horizontal direction of the matrix arrangement respectively,

the unit cell being connected to a power line connected to the reset transistor and the selecting transistor, and a signal line connected to the amplifying transistor, which are extending in the vertical direction of the matrix arrangement respectively,

the gate lines extending in a double line layer every two lines,

the first and the second photodiodes being located apart from each other to interpose the readout lines of the first and the second readout transistors,

the floating diffusion region being approximately rectangular, and

the first and the second transistors and the reset transistor being connected to respective sides of the floating diffusion region in a semiconductor substrate.

As described above, widening the area of the photodiode and arranging effectively the unit cells and the lines can be performed by connecting directly the pair of readout transistors and the reset transistor at the rectangular floating diffusion region common thereto and additionally by making the gate lines be double-layered lines.

A CMOS image sensor according to another aspect of the present invention comprises a plurality of unit cells arranged two-dimensionally in a matrix array with a predetermined pitch in the horizontal and vertical direction, the unit cell comprising a pair of two photodiodes, a pair of readout transistors connected to the photodiodes one by one to read out signals of the photodiodes, an amplifying transistor to amplify the signal, a reset transistor to reset the signal, and a selecting transistor to select the amplifying transistor, wherein

the two photodiodes of the unit cell is located apart from each other in the vertical direction of the matrix arrangement, the pair of the readout transistors being located between the pair of the photodiodes and sharing a floating diffusion region to be a drain,

the floating diffusion region being formed substantially in rectangular shape,

the reset transistor being provided directly adjacent to the floating diffusion region,

readout lines constituting respective gates of the readout transistors corresponding to the respective photodiodes being located facing to each other to interpose the floating diffusion region from both sides of the vertical direction, and

the amplifying transistor, the reset transistor, and the selecting transistor being formed in the region interposed by the readout lines of the pair of readout transistors.

The gates of the readout transistors corresponding to the respective photodiodes of the unit cell are located face to face together in such a manner as to interpose the approximately rectangular floating diffusion region from both sides of the vertical direction. Alternately, the gates of the readout transistors corresponding to the respective photodiodes of the unit cell are formed in such a manner as to be orthogonal to each other along two neighboring sides of the approximately rectangular floating diffusion region provided commonly to the photodiodes, and the reset transistor is provided directly adjacent to the floating diffusion region without a midway line.

As mentioned above, effective positioning of the unit cell and the line can be performed by connecting directly the pair of the readout transistors to the reset transistor at the common rectangular floating diffusion region.

### BRIEF DESCRIPTION OF THE DRAWINGS

FIG. 1 is a schematic circuit diagram showing the matrix in the first embodiment of the present invention;

FIG. 2 is a circuit diagram of the unit cell of the first embodiment according to the present invention;

FIG. 3 is a plan view showing the layout of the principal part of the first embodiment according to the present invention;

FIG. 4 is a schematic cross section along A-A′ line of the FIG. 3, showing the potential well to explain the first embodiment;

FIG. 5 is a pulse waveform diagram to explain the operation of the first embodiment;

FIG. 6 is a circuit diagram showing a variant of the first embodiment;

FIG. 7 is a schematic circuit diagram showing the matrix in the second embodiment of the present invention;

FIG. 8 is a circuit diagram of the unit cell of the second embodiment according to the present invention;

FIG. 9A is a plan view showing the layout of the principal part of the second embodiment according to the present invention;

FIG. 9B is a magnified plan view of the principal part of FIG. 9A;

FIG. 10 is a schematic circuit diagram showing the matrix of the conventional device;

FIG. 11 is a circuit diagram of the unit cell of the conventional device; and

FIG. 12 is a plan view showing the layout of the principal part of the conventional device.

### DETAILED DESCRIPTION OF THE INVENTION

Some embodiments of the present invention will be hereinafter explained referring to the drawings. Any part denoted by the same mark in each figure is the same part.

First Embodiment

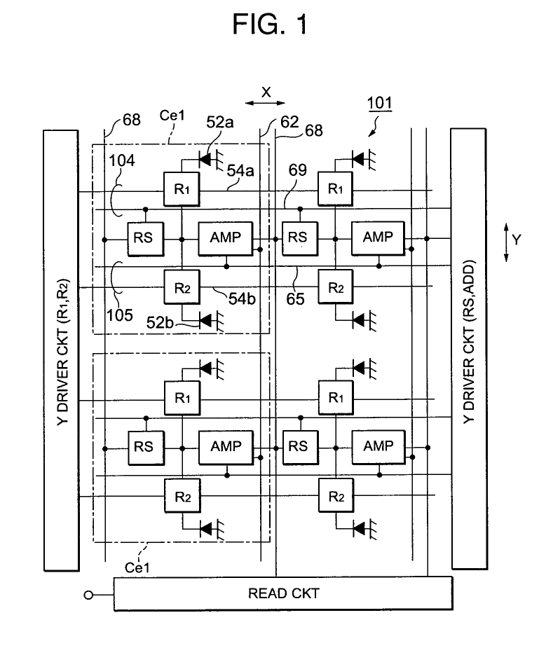

The first embodiment will be explained referring to FIG. 1 to FIG. 5. FIG. 1 shows a matrix diagram in which a plurality of unit cells Ce1 are arranged on a semiconductor substrate. R1 and R2 represent readout transistor gate regions to which readout pulses R1 and R2 are applied in order to read out signals of photodiodes 52a and 52b. A reset transistor gate portion RS and an amplifying transistor and selecting transistor portion AMP are connected thereto.

In the figure, Y Driver CKT (R1, R2), which is a peripheral circuit generating readout pulses R1, R2, is shown on the left side of the horizontal direction of the matrix. Y Driver CKT (RS, ADD), which is a peripheral circuit generating reset pulses and address pulses, is shown on the right side of the figure. A peripheral circuit READ CKT for reading out sequentially information of a signal line in the vertical direction of the matrix is shown on the bottom side of the figure.

A first and a second readout lines 54a, 54b to which a readout pulse is applied, a reset line 69 to which a reset pulse is applied, and a selecting line 65 to which an address pulse is applied extend in the horizontal direction X of the matrix. These lines are gate lines controlling the gate of each transistor. A power line 68 and a signal line 62 extend in the vertical direction of the matrix. The unit cell Ce1 is connected to the four gate lines 54a, 54b, 65, 69 extending in the horizontal direction, and to the power line 68 and signal line 62 extending in the vertical direction.

In this embodiment, the RS portion exists between the readout lines 54a and 54b, so that it does not cross the readout lines.

In the figure, a picture element portion 101 of the CMOS image sensor comprises a plurality of the unit cells Ce1 on a semiconductor substrate, arranged two-dimensionally in a matrix array in horizontal and vertical directions nearly like a square lattice. The picture element of one unit cell Ce1 comprises two photodiodes, i.e. the first and the second photodiodes 52a and 52b.

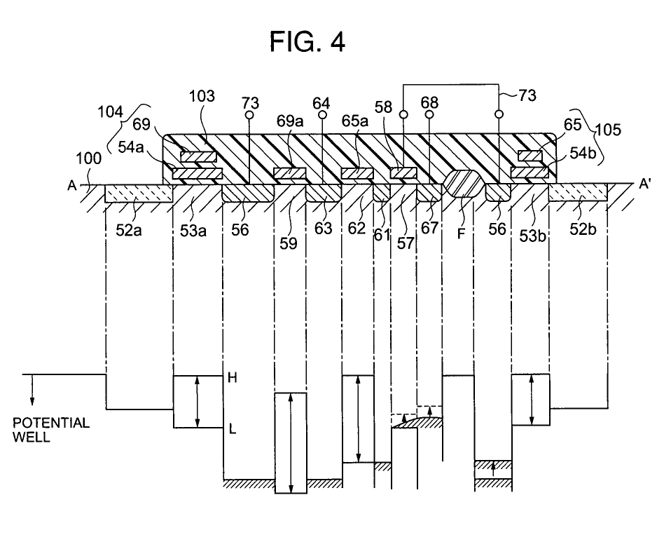

In this embodiment, the first readout line 54a of the first readout transistor 53a and the reset line 69 of the reset transistor 59 are superimposed together via an inter-layer insulation layer 103 (FIG. 4) as a double line layer 104. In the same way, the second readout line 54b of the second readout transistor 53b and the selecting line 65 of the selecting transistor 62 are superimposed together via the inter-layer insulation layer 103 (FIG. 4) as a double line layer 105.

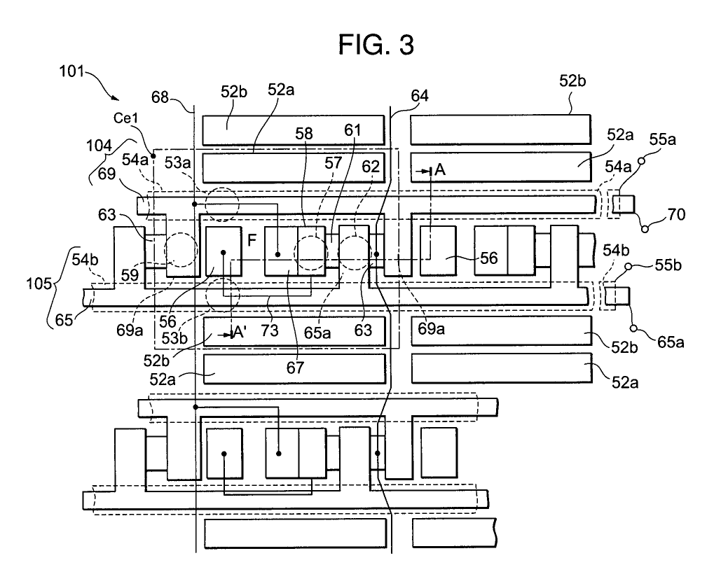

As shown in FIG. 3, the double line layers 104 and 105 are extended parallel to each other in the horizontal direction of the matrix arrangement in the layout. The photodiodes 52a and 52b are located on the outside of these line layers in such a manner as to interpose the first and the second readout transistors 53a and 53b, and the double line layers 104 and 105 inside thereof. The floating diffusion region 56 connected to the drains of the first and the second readout transistors, the reset transistor 59, the amplifying transistor 57, and the selecting transistor 62 are located on the inside region interposed by the double line layers.

The floating diffusion region 56 shapes rectangular, and the drains of the first and the second readout transistors 53a, 53b are connected to the opposite sides 56a, 56b of four sides of this region. The source of the reset transistor 59 is also connected to a side interposed by the two sides 56a, 56b.

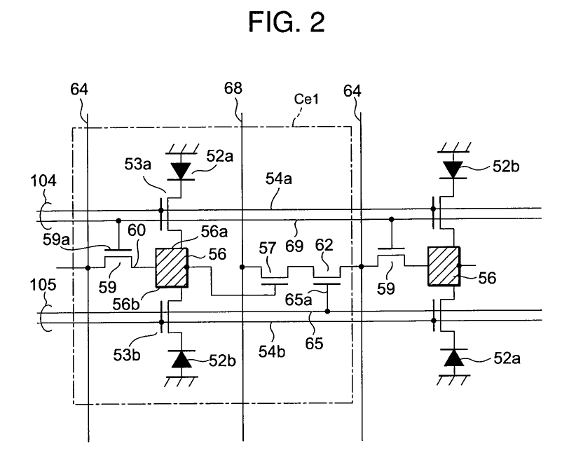

As shown in FIG. 2 in more detail, the readout transistors 53a, 53b are provided corresponding to the first and the second photodiodes 52a, 52b of each unit cell, and the sources of the transistors are connected to the photodiodes respectively. The readout lines 54a, 54b supplying readout pulses double as the gates of the respective readout transistors 53a, 53b, and the drains of the readout transistors 53a, 53b are formed by the common floating diffusion region 56. The first and the second photodiodes 52a, 52b share the amplifying transistor 57, the reset transistor 59, and the selecting transistor 62.

As shown in FIG. 3, either the first photodiode 52a or the second photodiode 52b, which are rectangular elongated in the horizontal direction in the same unit cell, is located horizontally a predetermined distance apart. In the vertical direction, a predetermined distance is prepared between the first photodiode 52a and the second photodiode 52b of the same unit cell. Alternatively, the first photodiode 52a of the neighboring unit cell in the horizontal direction may be adjacent to the second photodiode 52b so that the first photodiode 52a and the second photodiode 52b can be positioned one after the other.

Between the first photodiode 52a and the second photodiode 52b, the first readout line 54a and the second readout line 54b extend common to the unit cells Ce1 of columns arranged in the horizontal direction of the matrix arrangement. The first readout line 54a is the gate line of the readout transistor 53a of the first photodiode 52a side. The second readout line 54b is the gate line of the readout transistor 53b of the second photodiode 52b side. The readout lines 54a, 54b are formed by polycrystalline silicon and connected to readout line ends 55a, 55b supplying a readout pulse respectively.

Between the gate (the first readout line) 54a of the readout transistor 53a and the gate (the second readout line) 54b of the readout transistor 53b, the approximately rectangular floating diffusion region 56 and an approximately rectangular source diffusion region 67 of the amplifying transistor 57 separated therefrom by a predetermined distance by the aid of an element separation region F are located one by one in the horizontal direction. A rectangular gate 58 of the amplifying transistor 57 is located adjacent to the source diffusion region 67, and a rectangular drain 61 of the amplifying transistor 57 is located adjacent to the gate 58. A rectangular drain 63 of the selecting transistor 62 is located a predetermined distance apart from the drain region 61 as the source thereof for each unit cell Ce1.

On the lower layer that comprises the gate (the first readout line) 54a of the readout transistor 53a and the gate (the second readout line) 54b of the readout transistor 53b, the reset line 69 of polycrystalline silicon connected to the gate 69a of the reset transistor 59 and the selecting line 65 connected to the gate 65a of the selecting transistor 62 are extending in the horizontal direction with an inter-layer insulating layer provided between each readout line and the reset line or the selecting line. Furthermore, the gate 69a of the reset transistor 59 is formed in such a manner as to protrude from the reset line 69, and located between the floating diffusion region 56 and the drain 63 of the selecting transistor 62 of the neighboring unit cell Ce1 in the horizontal direction, or between the drain 63 of the selecting transistor 62 and the floating diffusion region 56 of the neighboring unit cell Ce1 in the horizontal direction.

The gate 65a of the selecting transistor 62 is formed in such a manner as to protrude from the selecting line 65, and located between the drain 61 of the amplifying transistor 57 and the drain 63 of the selecting transistor 62. A reset line terminal 70 supplying a reset pulse is connected to the reset line 69 at the end thereof, and a selecting line terminal 65a supplying a selecting pulse is connected to the selecting line 65 at the end thereof.

In each unit cell Ce1 having the layout constituted like the above, the power line 64 of aluminum is directly laid in the vertical direction. The drain of the reset transistor 59 and the drain 63 of the selecting transistor 62 of the unit cell Ce1 are one and the same, and the power line 64 connects each unit cell together in a column unit. For the source diffusion region 67 of the amplifying transistor 57 of each unit cell Ce1 arranged in the vertical direction like a column, a signal line 68 outputting a signal read out by a readout pulse connects them together by an aluminum line. Moreover, a connecting line 73 connecting the floating diffusion region 56 to the gate 58 of the amplifying transistor 57 is laid by an aluminum line in every unit cell Ce1.

In the construction above as shown in FIG. 4, the gate 58 of the amplifying transistor 57 may be formed by the same layer as the gates 54a, 54b of the readout transistor 53a, 53b or by the same layer as the gate 69a of the reset transistor 59 and the gate 65a of the selecting transistor 62 with the same polycrystalline silicon, or otherwise may be formed by different polycrystalline silicon layers or metal layers as different layers from each other.

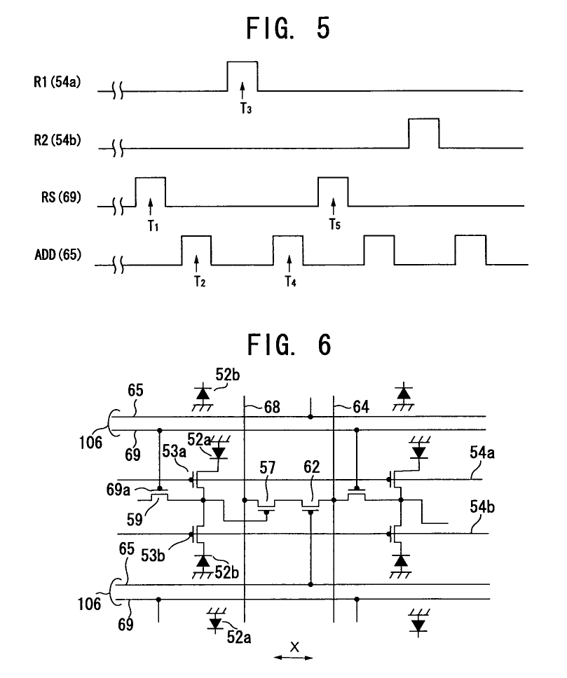

As shown in FIG. 6, the selecting line 65 and the reset line 69 may pass through the spacing between the photodiodes 52a and 52b of the vertically neighboring unit cells as a double-layered line 106.

Brief of operation of the CMOS image sensor will be described with reference to the waveforms of the driving pulse shown in FIG. 5, the cross section at A-A′ line of FIG. 3, and the variation of the potential well at each point shown in FIG. 4.

FIG. 5 shows timing charts of the readout pulses R1, R2 applied to the gates (readout lines) of the readout transistors 53a, 53b, the waveform RS (69) of the reset pulse imposed on the reset line 69 to be applied to the gate 69a of the reset transistor, and the waveform ADD (65) of the address pulse imposed on the selecting line 65 to be applied to the gate 65a of the selecting transistor.

FIG. 4 shows the photodiodes 52a, 52b, and a metal line 73 as a connecting line from the floating diffusion region 56 to the gate of the amplifying transistor 57 prepared by diffusion process on a semiconductor substrate 100.

The figure also shows variation of the potential well corresponding to each portion. The amount of variation of the potential well corresponding to each high level H and low level L of the pulse waveform is designated by arrows.

The driving method is as follows. First of all, the reset pulse (RS (69)) applied to the gate 69a of the reset transistor is set to high level, and the potential of the floating diffusion region 56 is reset to the drain potential (a constant potential) of the reset transistor (T1). Then high level of the address pulse (ADD (65)) is applied to the gate 65a of the selecting transistor, and the potential of the source diffusion region 67 is detected before the signals from the photodiode 52a are transferred (T2).

Subsequently, the readout pulse (R1 (54a)) being applied to the gate 54a of the readout transistor is set to high level, and the signals are transferred from the photodiode 52a to the floating diffusion region 56 (T3). This potential variation of the floating diffusion region 56 is transmitted to the gate 58 of the amplifying transistor via the connecting line 73. When the address pulse applied to the gate 65a of the selecting transistor becomes high level, the potential of the source diffusion region 67 varies (T4). In this case, noise component of the output circuit is suppressed by taking the difference between the state with the signals and the one without the signals. Then, high level of the reset transistor is applied again to the gate 69a of the reset transistor, and the potential of the floating diffusion region 56 is again reset to the drain potential (a constant potential) of the reset transistor (T5).

In the same way, signals of the photodiode 52b are read out by the readout pulse (R2 (54b)).

For the first and the second photodiodes 52a, 52b of each unit cell Ce1 lining up horizontally adjacent to the lower side in the vertical direction, i.e. the third and the fourth lines of the picture element rows, readout of the signals is carried out in the same way as the first and the second lines mentioned above by sharing the floating diffusion region. By repeating the above for each following line, all first and second photodiodes 52a, 52b, which are picture elements of the picture element portion, are read out.

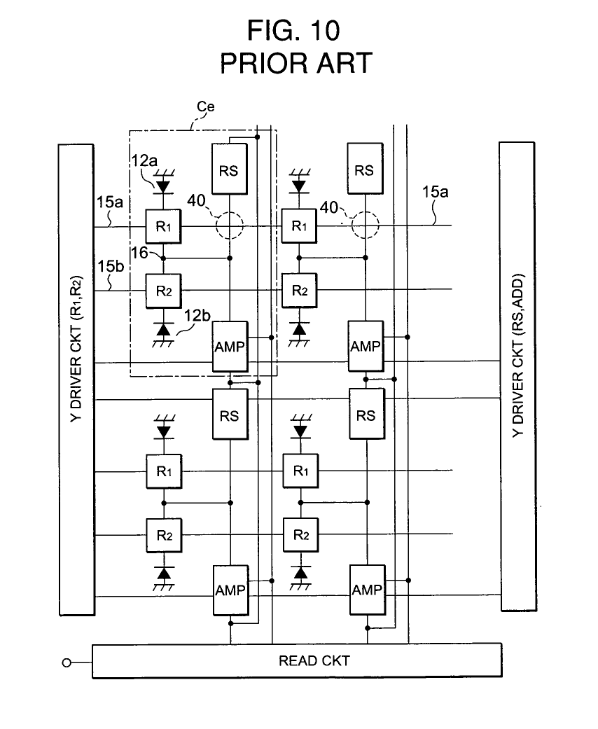

Because the floating diffusion region 56 is further provided between the gates 54a and 54b of the readout transistors 53a, 53b located face to face between the readout transistors 53a and 53b, and because the reset transistor 59 resetting the floating diffusion region 56 to a predetermined potential after the signal is read out is provided adjacent to the floating diffusion region 56, the connecting line 32 connecting the floating diffusion region 16 to the source 20 of the reset transistor 19, which is necessary for the conventional layout (FIG. 10 to FIG. 12), is not required anymore. As a result, the output circuit in the unit cell Ce1 can be highly integrated. That leads to high integration for the whole sensors and improvement of the resolution thereof.

On the other hand, because the source of the reset transistor and the connecting line 32 (FIG. 12) to connect it for the conventional device is not necessary in accordance with this embodiment, variation of the signal output to the signal charge, i.e. the amplification gain can improve compared to the conventional device. Increment of the amplification gain reaches approximately 30%.

The first photodiode 52a and the second photodiode 52b are made elongated rectangles and located in the horizontal direction apart from each other by a predetermined distance defined by the width of the element-separating region. Furthermore, because a common output circuit is provided between the first photodiode 52a and the second photodiode 52b for every unit cell Ce1 in the vertical direction, the width of the element-separating region between the photodiodes becomes approximately a half with respect to each photodiode unit. Therefore the areas of the first photodiode 52a and the second photodiode 52b can be widened, i.e. occupation ratio thereof to the area of the whole unit cell Ce1 can be increased.

The horizontal width of the floating diffusion region 56 for reading-out is sufficiently narrow compared to the horizontal width of the photodiode 52a as shown in FIG. 3, and solely the element-separating region exists in the gap between the photodiodes in the horizontal direction. Therefore the photodiode 52a can be offset in the horizontal direction X to the photodiode 52b vertically adjacent to the photodiode 52a as shown in FIG. 6. Thus a layout that makes picture elements offset to each other like a checker pattern to improve the resolution can be easily put to practical use.

Second Embodiment

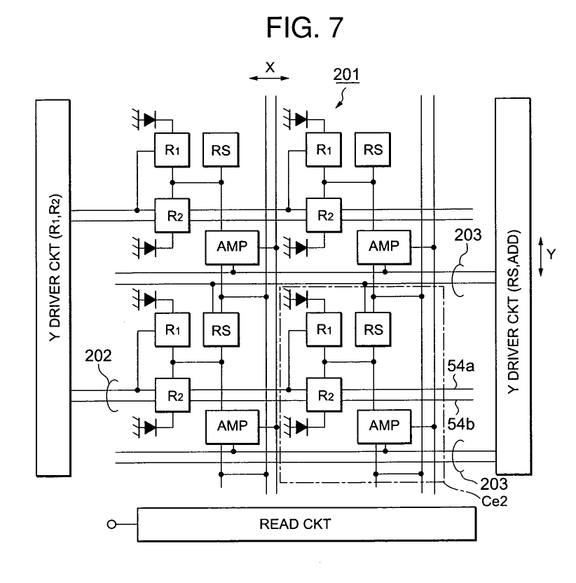

Referring to FIG. 7 to FIG. 9, the second embodiment will be explained. FIG. 7 shows a matrix diagram: R1 and R2 denote the readout transistor gate regions of the photodiodes to which the readout pulses R1, R2 are applied; RS denotes the reset transistor gate portion; AMP denotes the amplifying transistor and the selecting transistor portion.

In the figure, the peripheral circuit Y Driver CKT (R1, R2) generating readout pulses R1, R2 is shown on the left side, and the peripheral circuit Y Driver CKT (RS, AMP) generating reset pulses and address pulses is shown on the left side of the figure. The peripheral circuit READ CKT to read out sequentially information of the signal line is shown on the bottom side of the figure.

The embodiment shown in FIG. 7 has no crossover portion by making the RS portion detour the readout line 54a.

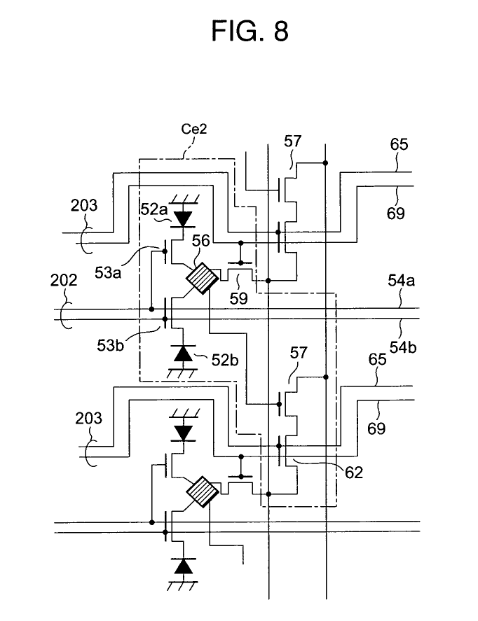

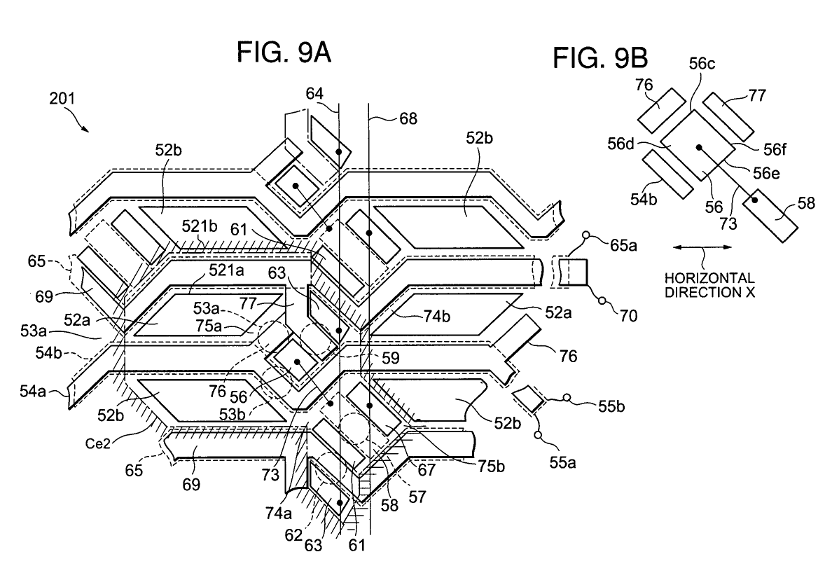

In FIG. 8, FIG. 9A and FIG. 9B, the picture element portion 201 of the CMOS image sensor is constituted of a plurality of unit cells Ce2 arranged in two-dimensional matrix, and the picture element of one unit cell comprises the first and the second photodiodes 52a, 52b, which is the same circuit construction as the one shown in FIG. 2.

The readout transistors 53a, 53b are provided corresponding to the first and the second photodiodes 52a, 52b respectively, and the readout line terminals 55a, 55b are connected to the gates 54a, 54b of the readout transistors 53a, 53b respectively. Drains of the readout transistors 53a, 53b are formed by a common floating diffusion region 56. The amplifying transistor 57, the reset transistor 59 and the selecting transistor 62 are provided commonly to the first and the second photodiodes 52a, 52b.

As shown in FIG. 9A, either the first photodiodes 52a or the second photodiodes 52b in the shape of a parallelogram are arranged apart from each other by a predetermined distance in the horizontal direction, and the first photodiode 52a and the second photodiode 52b are arranged one after the other with a predetermined distance in the vertical direction. The first photodiode 52a and the second photodiode 52b arranged as the above are positioned together in such a manner that the long sides thereof are parallel to the horizontal direction. For example, the first photodiode 52a is arranged in such a manner that the lower long side is positioned in left direction to the upper long side, and the second photodiode 52b is arranged in such a manner that the lower long side is positioned in right direction to the upper long side. In the same unit cell Ce2, the lower long side 521a of the first photodiode 52a and the upper long side 521b of the second photodiode 52b are positioned face to face with each other via a predetermined distance in the vertical direction.

Between the first photodiode 52a and the second photodiode 52b of the same unit cell Ce2, a first double-layered gate line 202 extending horizontally from the space between the long sides 521a and 521b facing to each other of the photodiodes 52a and 52b to the neighboring unit cell Ce2 is provided. The gate line 202 includes a first V-shaped portion 74a bending nearly at a right angle protruding downward in the vertical direction. The gate 54a of the readout transistor 53a formed by polycrystalline silicon is provided in the lower layer of the double-layered construction, and an inter-layer insulating layer is provided in the middle thereof. In the upper layer thereof, the gate 54b of the readout transistor 53b is also formed by polycrystalline silicon. These elements are arranged horizontally in line so that each neighboring unit cell Ce2 may have the same construction.

On the other hand, a second double-layered gate line 203 extending in the horizontal direction is provided between two unit cells Ce2 vertically adjacent to each other. The second double-layered gate line is provided between the lower long side 521b of the second photodiode 52b and the upper long side 521a of the first photodiode 52a of the neighboring unit cell Ce2. The gate line 203 forms a horizontal portion parallel to the both long sides of the diodes and a second V-shaped portion 74b bending nearly at a right angle protruding downward in the vertical direction between the unit cell and the neighboring unit cell Ce2.

The gate 69 of the reset transistor 59 formed by polycrystalline silicon is provided in the lower layer of the double-layered construction. In the upper layer thereof, the gate 65 of the selecting transistor 62 is also formed by polycrystalline silicon through an inter-layer insulating layer provided in the middle thereof. These elements are arranged horizontally in line so that each neighboring unit cell Ce2 may have the same construction.

In this way, a first compartment 75a in which the floating diffusion region 56 is located and a second compartment 75b in which the amplifying transistor 57 is located are formed. The first compartment 75a is formed approximately in the shape of a square by the aid of the first V-shaped portion 74a, the second V-shaped portion 74b, the right short side of the first photodiode 52a, and the right short side of the second photodiode 52b. The compartment is formed adjacent to the right of the first photodiode 52a in the horizontal direction. The second compartment 75b is formed on the right of the second photodiode 52b in the horizontal direction interposing the first V-shaped portion 74a between them.

The gate 54a of the readout transistor 53a is a portion 76 protruding at a right angle along the right short side of the first photodiode 52a toward the inside of the first compartment 75a from the opening end of the first V-shaped portion 74a, extending at the same depth as the gate 54a. The gate 69 of the reset transistor 59 is provided with a protruding portion 77 whose root part is perpendicular to the reset line and whose top end crosses the protruding portion 76 of the gate 54a at a right angle, toward the inside of the first compartment 75a from the horizontal portion at the same depth as the gate 69. The protruding portion 76 of the gate 54a and the protruding portion 77 of the gate 69 are formed at different depths having an inter-layer insulating layer provided between them.

Readout terminals 55a and 55b supplying readout pulses are connected to the gates 54a and 54b of the readout transistors 53a and 53b respectively. The reset line 69 supplying a reset pulse is connected to the gate 77 of the reset transistor 59, and the gate of the selecting transistor 62 is formed by the selecting line 65 supplying a selecting pulse.

The rectangular floating diffusion region 56 and the trapezoidal drain 63 of the selecting transistor 62 are located in the first compartment 75a in such a manner that they interpose the protruding portion 77 forming the gate of the reset transistor 59.

As shown by FIG. 9B in magnification, the rectangular floating diffusion region has first to fourth sides 56c, 56d, 56e and 56f arranged in the direction of approximately 45 degrees to the horizontal direction X of the matrix arrangement. Along the first side 56c and the second side 56d adjacent to each other, the gates 76 and 54b of the first and the second readout transistors are located in such a manner as to be orthogonal to each other. The protruding portion 77 of the gate 69 of the reset transistor 62 is located facing to the fourth side 56f. The amplifying transistor 57 is located in the direction of the third side 56e, and a metal line 73 is pulled out from the floating diffusion region 56 to the gate 58 of the amplifying transistor.

In the second compartment 75b, the rectangular source diffusion region 67 and the rectangular drain 61 of the amplifying transistor 57 are arranged in such a manner as to interpose the rectangular gate 58 of the amplifying transistor 57, which is parallel to the left short side of the second photodiode 52b.

To each unit cell Ce2 with the layout mentioned above, a power line 64 of aluminum is directly laid in order to connect together each drain 63 of the selecting transistor 62, which doubles as the drain of the reset transistor 59, of each unit cell Ce2 arranged in the vertical direction Y. In the same way, to the source diffusion region 67 of the amplifying transistor 57 of each unit cell Ce2 arranged in the vertical direction, a signal line 68 outputting a signal read out by a readout pulse is laid to connect each source diffusion region 67 together with an aluminum line. Furthermore, a connecting line 73 of aluminum connecting the floating diffusion region 56 to the gate 58 of the amplifying transistor 57 is laid for each unit cell Ce2.

As mentioned above, a double-layered line 202 formed by two layers of the gate 54a of the readout transistor 53a and the gate 54b of the readout transistor 53b superimposed in the thickness direction is extended in the horizontal direction X, and a double-layered line 203 formed by the gate 69 of the reset transistor 59 and the gate 65 of the selecting transistor 62 superimposed in the thickness direction is also extended in the horizontal direction X. Moreover, the gate lines 54a, 54b and the gate lines 65, 69 superimposed in two layers in the thickness direction are arranged one after the other in the vertical direction Y. Either the first photodiode 52a or the second photodiode 52b of parallelogram is located between the two double-layered lines alternately arranged in a unit cell in the horizontal direction. By arranging them one after the other in the vertical direction, the areas of the first photodiode 52a and the second photodiode 52b can be widened, so that occupation rate thereof to the whole unit cell Ce2 can be increased.

The first and the second V-shaped portions 74a and 74b bending at approximately a right angle are formed on the gates 54a, 54b, 69, and 65 of the readout transistors 53a, 53b, the reset transistor 59 and the selecting transistor 62 for each unit cell Ce2, in order to provide the first and the second compartments 75a, 75b. The floating diffusion region 56 common to the two readout transistors 53a, 53b and the gate 58 of the amplifying transistor 57, etc. are arranged in the compartments 75a, 75b. Because the rectangular floating diffusion region 56 is arranged in the tilted state to the horizontal direction by about 45 degrees, the width in the vertical direction decreases to approximately 0.7 times thereof.

Consequently, the location distance between the first photodiode 52a and the second photodiode 52b in the vertical direction is determined only by the width of the element separating region at the neighboring unit cell Ce2, and the widths of the gates 54a, 54b, 69, and 65 of the superimposed readout transistors 53a, 53b, the reset transistor 59, and the selecting transistor 62, so that high integration in the vertical direction can be performed.

In addition, a connecting line indispensable for the conventional layout to connect the floating diffusion region to the source 60 of the reset transistor 59 is not necessary because the floating diffusion region 56 is provided in the first and the second compartments 75a, 75b and further the reset transistor 59 is provided adjacent to the floating diffusion region 56 to reset it to a predetermined potential after signals are read out. By the construction described above, the output circuit in the unit cell Ce2 can be highly integrated, so that high integration of the whole sensor can be attempted and the resolution can be improved.

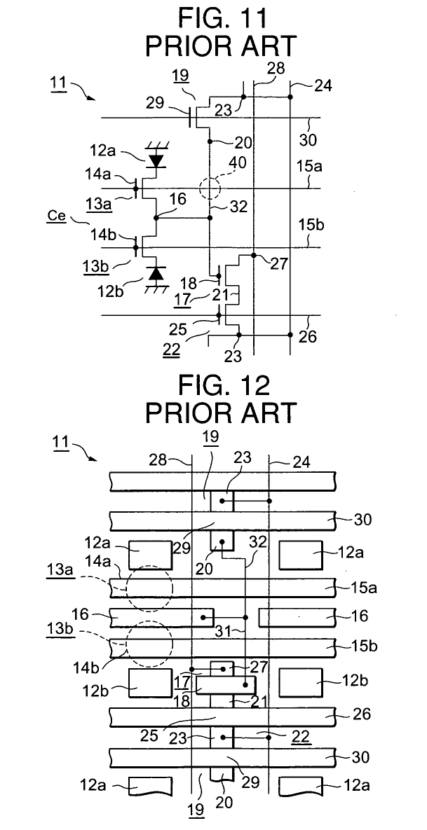

Comparing the embodiment of the present invention with the conventional device, the characteristic feature in the conventional device shown in FIG. 10 is that a readout line 15a forms a crossover portion 40 at a point between the floating diffusion region and RS as shown by the dotted circle in the figure, and thereby a source region 20 of the reset transistor and a connecting line 32 are required as shown by FIGS. 11, 12.

In the matrix diagram of the present invention shown in FIG. 7, the readout line can be detoured to eliminate the crossover portion.

As understood by the aforementioned explanation, the present invention can effectively locate elements, lines etc. constituting the unit cell, and integrate them highly. Furthermore, the invention can play some effects i.e. increasing the area of the photodiode by more than 30%, improving the dynamic gain by improving the charge-voltage conversion gain, and providing a high sensitive sensor.

What is claimed is:

1. A CMOS image sensor having a plurality of unit cells comprising a photodiode and a plurality of MOS transistors, the plurality of the unit cells being arranged in a matrix array on a semiconductor substrate, wherein
the unit cell comprises a first and a second photodiodes formed on a semiconductor substrate, a first readout transistor connected to the first photodiode and reading out signals thereof, a second readout transistor connected to the second photodiode and reading out signals thereof, a floating diffusion region transmitting the signals and connected to the first and the second readout transistors, a reset transistor connected to the floating region and resetting the potential of the region, an amplifying transistor having a gate connected to the floating diffusion region and amplifying the signals, and a selecting transistor selectively addressing the amplifying transistor,
the unit cell being connected to four address lines, comprising two readout lines of the first and the second readout transistors, a reset line of the reset transistor and a select line of the selecting transistor, all of them extending in the horizontal direction of the matrix arrangement respectively,
the unit cell being connected to a power line connected to the reset transistor and the selecting transistor, and to a signal line connected to the amplifying transistor, both of them extending in the vertical direction of the matrix arrangement respectively,
the address lines being superimposed in a double-layer every two lines and extended,
the first and the second photodiodes being located apart from each other with the first and the second readout transistors interposed between them,
the floating diffusion region being approximately rectangular, and
the first and the second readout transistors and the reset transistor being connected to respective sides of the floating diffusion region within a semiconductor substrate.

2. The CMOS image sensor as stated in claim 1, wherein the first and the second readout transistors are connected to sides of the floating diffusion region facing thereto, and the reset transistor is connected to a side interposed by the facing sides.

3. The CMOS image sensor as stated in claim 1, wherein the first and the second readout transistors are connected to neighboring sides of the floating diffusion region.

4. The CMOS image sensor as stated in claim 1, wherein the floating diffusion region is constituted to be one of electrodes of the first readout transistor, the second readout transistor and the reset transistor, which is common thereto.

5. The CMOS image sensor as stated in claim 1, wherein the first and the second readout transistors, the floating diffusion region, the reset transistor, the amplifying transistor and the selecting transistor are located in a region interposed by four gate lines extending respectively in the horizontal direction of the matrix arrangement.

6. The CMOS image sensor as stated in claim 1, wherein the first and the second photodiodes are located facing to the vertical direction of the matrix arrangement.

7. The CMOS image sensor as stated in claim 1, wherein the first and the second photodiodes are located facing to the vertical direction of the matrix arrangement and offsetting to each other in the horizontal direction.

8. The CMOS image sensor as stated in claim 1, wherein the first to the fourth sides of the rectangular floating diffusion region are arranged in approximately 45 degrees to the horizontal direction of the matrix arrangement, the gates of the first and the second readout transistors being arranged to be orthogonal to each other along the neighboring first and second sides, the gate of the reset transistor being arranged facing to the third side, the amplifying transistor being arranged in the direction of the fourth side, and a metal line being pulled out from the floating diffusion region to the gate of the amplifying transistor.

9. The CMOS image sensor as stated in claim 1, wherein one of the gate lines of the double layer is the readout line of the first readout transistor and the reset line of the reset transistor.

10. The CMOS image sensor as stated in claim 1, wherein one of the gate lines of the double layer is the readout line of the first readout transistor and the readout line of the second readout transistor.

11. The CMOS image sensor as stated in claim 1, wherein the four address lines extending in the horizontal direction of the matrix arrangement are formed by polycrystalline silicon and the two lines extending in the vertical direction are metal.

12. A CMOS image sensor having a plurality of pixel unit cells comprising a photodiode and a plurality of MOS transistors, the pixel unit cells being arranged in a matrix array on a semiconductor substrate, wherein
the unit cell comprises a first and a second photodiodes formed on a semiconductor substrate, a first readout transistor whose source is connected to the first photodiode and reading out signals thereof, a second readout transistor connected to the second photodiode at the source thereof and reading out signals thereof, a floating diffusion region transmitting the signals and connected to the drains of the first and the second readout transistors, a reset transistor connected to the floating diffusion region at the source thereof and resetting a potential of the region, an amplifying transistor connected to the floating diffusion region at the gate thereof via a metal line and amplifying the signals, and a selecting transistor connected to the source of the amplifying transistor at the drain thereof and addressing selectively the amplifying transistor,
the unit cell being connected to four gate lines, comprising two readout lines of the first and the second readout transistors, a reset line of the reset transistor and a selecting line of the selecting transistor, all of them extending in the horizontal direction of the matrix arrangement respectively,
the unit cell being connected to a power line connected to the drain of the reset transistor and the drain of the selecting transistor, and to a signal line connected to the source of the amplifying transistor, both of them extending in the vertical direction of the matrix arrangement respectively,
the gate lines being superimposed in a double-layer every two lines and extended,
the first and the second photodiodes being arranged apart from each other with interposing the gate lines of the first and the second readout transistors,
the floating diffusion region being approximately rectangular, and
the first and the second readout transistors and the reset transistor being connected to respective sides of the floating diffusion region within a semiconductor substrate.

13. A CMOS image sensor having a plurality of unit cells comprising:
a pair of two photodiodes;
a pair of readout transistors connected to the photodiodes one by one and reading out signals of the photodiodes;
an amplifying transistor amplifying the signals;
a reset transistor resetting the signals; and
a selecting transistor selecting the amplifying transistor,
the plurality of the unit cells being arranged in a matrix array two-dimensionally at a predetermined pitch like approximately a lattice in the vertical direction and the horizontal direction, and respective gates of the pair of the readout transistors, the reset transistor and the selecting transistor being formed by gate lines extending in the horizontal direction of the matrix arrangement, wherein
the gate lines form a double-layered line layer in which at least two lines thereof are superimposed together in the layer direction,
the two photodiodes of the unit cell being located apart from each other in the vertical direction of the matrix arrangement, the pair of the readout transistors sharing a floating diffusion region to become a drain and being located between the two photodiodes,
the floating diffusion region being formed in an approximately rectangular shape, and
the reset transistor being provided directly adjacent to the floating diffusion region.

14. The CMOS image sensor as stated in claim 13, wherein the gates of the pair of the readout transistors are located to be orthogonal to each other along neighboring sides of the rectangular floating diffusion region, the pair of the photodiodes being located horizontally in the direction of approximately 45 degrees to the gates of the readout transistors, the gate of the amplifying transistor being located in the direction of one of the remaining sides of the floating diffusion region that are not covered by the gates of the reset transistor, and a line being pulled out from the floating diffusion region to the gate of the amplifying transistor.

15. A CMOS image sensor having a plurality of unit cells comprising:
a pair of two photodiodes;
a pair of readout transistors connected to the photodiodes one by one and reading out signals of the photodiodes;
an amplifying transistor amplifying the signals;
a reset transistor resetting the signals; and
a selecting transistor selecting the amplifying transistor,
the plurality of the unit cells being arranged in a matrix array two-dimensionally like approximately a lattice at a predetermined pitch in the vertical direction and the horizontal direction, wherein
the two photodiodes of the unit cell are located apart from each other in the vertical direction of the matrix arrangement, the pair of the readout transistors sharing a floating diffusion region to become a drain and being positioned between the pair of the photodiodes, and the gates of the pair of the readout transistor being located to correspond to respective photodiodes,
the floating diffusion region being formed in an approximately rectangular shape,
the reset transistor being located directly adjacent to the floating diffusion region,
readout lines constituting respective gates of the readout transistors corresponding to respective photodiodes being positioned in parallel together to interpose the floating diffusion region from the both sides of the vertical direction, and
the amplifying transistor, the reset transistor, and the selecting transistor being all formed in a region interposed by the readout lines of the pair of the readout transistors.

16. The CMOS image sensor as stated in claim 15, wherein respective gates of the readout transistors corresponding to the photodiodes of the unit cells are located to be orthogonal to each other along neighboring sides of the approximately rectangular floating diffusion region, and the reset transistor is provided adjacent to the floating diffusion region.

17. The CMOS image sensor as stated in claim 15, wherein the centers of the pair of the two photodiodes adjacent to the matrix in the vertical direction are horizontally offset to each other.
